(19) United States
(12) Patent Application Publication
(10) Pub. No.: US 2024/0363824 A1
(43) Pub. Date: Oct. 31, 2024

(54) ARRAY SUBSTRATE, LIGHT EMITTING SUBSTRATE AND DISPLAY DEVICE

(71) Applicants: Hefei BOE Ruisheng Technology Co., Ltd., Hefei, Anhui (CN); BOE Technology Group Co., Ltd., Beijing (CN)

(72) Inventors: Ningyu LUO, Beijing (CN); Zouming XU, Beijing (CN); Xintao WU, Beijing (CN); Jiawei XU, Beijing (CN); Jie WANG, Beijing (CN); Tingwei HAN, Beijing (CN); Wenzhuo TANG, Beijing (CN)

(21) Appl. No.: 18/766,707

(22) Filed: Jul. 9, 2024

Related U.S. Application Data
(63) Continuation of application No. PCT/CN2023/087974, filed on Apr. 13, 2023.

(51) Int. Cl. H01L 33/62; H01L 25/075; H01L 25/16; H01L 27/12

(52) U.S. Cl. CPC H01L 33/62; H01L 25/0753; H01L 25/167; H01L 27/124

(57) ABSTRACT

An array substrate includes a base substrate, a conductive layer on a side of the base substrate, a light adjustment layer on a side of the conductive layer away from the base substrate, a plurality of signal lines on a side of the base substrate away from the conductive layer, and a protective layer between the light adjustment layer and the base substrate. The conductive layer includes a plurality of pads electrically connected with electronic elements. An orthographic projection of at least part of the light adjustment layer on the base substrate does not overlap an orthographic projection of the conductive layer on the base substrate, and is located in gaps between orthographic projections of adjacent signal lines on the base substrate. An orthographic projection of the protective layer on the base substrate at least covers the orthographic projection of the at least part on the base substrate.

### CROSS-REFERENCE TO RELATED APPLICATION

The present disclosure is a continuation application of PCT application No. PCT/CN2023/087974 filed on Apr. 13, 2023, the entire contents of which are incorporated herein by reference.

### TECHNICAL FIELD

The present application relates to a field of display technology, in particular to an array substrate, a light emitting substrate, and a display device.

### BACKGROUND

Mini-LEDs and Micro LEDs are a novel LED display technology derived on the basis of small-pitch LEDs, also referred to as sub-millimeter light emitting diodes. Since they have relatively good display effect and give people light and thin experience, and also have advantages such as high contrast and long service life, they have obvious use trend in the display field.

### SUMMARY

The present application provides an array substrate, a light emitting substrate and a display device.

According to a first aspect of embodiments of the present application, an array substrate is provided. The array substrate includes:
a base substrate;
a conductive layer located on a side of the base substrate, where the conductive layer includes a plurality of pads, and the pads are configured to be electrically connected with electronic elements;
a light adjustment layer located on a side of the conductive layer away from the base substrate;
a plurality of signal lines located on a side of the base substrate away from the conductive layer; an orthographic projection of at least part of the light adjustment layer on the base substrate does not overlap an orthographic projection of the conductive layer on the base substrate, and is located in gaps between orthographic projections of adjacent signal lines on the base substrate;
a protective layer located between the light adjustment layer and the base substrate, where an orthographic projection of the protective layer on the base substrate at least partially covers the orthographic projection of the at least part on the base substrate.

In an embodiment, the protective layer is made of a conductive material, and the protective layer is connected with a constant electrical signal.

In an embodiment, an orthographic projection of the protective layer on the base substrate covers gaps between orthographic projections of any two adjacent signal lines on the base substrate.

In an embodiment, the protective layer includes a plurality of protective portions, and an orthographic projection of one protective portion on the base substrate covers an orthographic projection of one of the gaps on the base substrate.

In an embodiment, an edge of the orthographic projection of the protective portion on the base substrate is located outside an edge of an orthographic projection of one of the gaps on the base substrate.

In an embodiment, the protective layer includes at least one protective portion group, and the at least one protective portion group each includes a plurality of protective portions arranged in parallel; the array substrate includes at least one signal line group, and the at least one signal line group each includes a plurality of signal lines arranged in parallel, and an arrangement trend of the signal lines in the signal line group is same as an arrangement trend of the protective portions in the protective portion group; and the protective layer further includes a connecting portion, and at least two protective portions in a same protective portion group are connected through the connecting portion.

In one embodiment, ends, on a same side, of the multiple protective portions in the same protective portion group are connected with the connecting portion.

In an embodiment, the protective layer is located on a side of the conductive layer away from the light adjustment layer.

In an embodiment, the protective layer is made of a conductive material, and the array substrate further includes an insulating layer located between the protective layer and the conductive layer.

In an embodiment, the conductive layer includes a conductive wire connected with a constant signal, the insulating layer is provided with a through hole, and the conductive wire is lapped with the protective layer through the through hole.

In an embodiment, the protective layer is made of a non-conductive material, and the orthographic projection of the protective layer on the base substrate covers an orthographic projection of the light adjustment layer on the base substrate.

In an embodiment, the conductive layer includes a first conductive sub-layer and a second conductive sub-layer located on a side of the first conductive sub-layer away from the base substrate, and the pads are located in the second conductive sub-layer.

According to a second aspect of the embodiments of the present application, there is provided a light emitting substrate including one or more electronic elements and the array substrate described above; the electronic elements are connected with the pads; and the electronic elements include one or more light emitting elements.

In one embodiment, the light-emitting elements are mini LEDs or Micro LEDs.

According to a third aspect of the embodiments of the present application, there is provided a display device including the above-mentioned light emitting substrate.

According to the array substrate, the light emitting substrate and the display device provided by the embodiments of the present application, the protective layer is arranged between the light adjustment layer and the base substrate, the orthographic projection of at least part of the light adjustment layer on the base substrate does not overlap with the orthographic projection of the conductive layer on the base substrate and is located in the gaps between the orthographic projections of the adjacent signal lines on the base substrate. The orthographic projection of the protective layer on the base substrate covers the orthographic projection of the at least part of the light adjustment layer on the base substrate. The energy of the laser is weakened when the laser adopted for preparing the signal lines is propagated to the protective layer, and then the energy of the laser is weak when the laser is transmitted to the at least part of the light adjustment layer, so that the problems of bulging, discoloration, peeling away from the adjacent film layer and the like because the at least part of the light adjustment layer absorbs a large amount of laser energy can be avoided. For the area where the orthographic projection of the conductive layer on the base substrate does not overlap with the orthographic projection of the protective layer on the base substrate, when the laser is transmitted to the area, the conductive layer can also weaken the energy of the laser, and the problems of bulging, discoloration, peeling off from the adjacent film layer(s) and the like are avoided when the other areas of the light adjustment layer absorb a large amount of laser energy. It can be known that according to the embodiments of the present application, the reliability of the array substrate can be improved, and the product yield is improved.

### BRIEF DESCRIPTION OF DRAWINGS

FIG. 1 is a partial cross-sectional view of an array substrate provided by an exemplary embodiment of the present application;

FIG. 2 is a partial structural schematic diagram of an array substrate provided by an exemplary embodiment of the present application;

FIG. 3 is a partial structural schematic diagram of a first conductive sub-layer provided by an exemplary embodiment of the present application;

FIG. 4 is a partial cross-sectional view of an array substrate provided by another exemplary embodiment of the present application;

FIG. 5 is a partial structural schematic diagram of a protective layer provided by an exemplary embodiment of the present application;

FIG. 6 is a partial cross-sectional view of an array substrate provided by still another exemplary embodiment of the present application.

### DETAILED DESCRIPTION

Exemplary embodiments will be described in detail herein, examples of which are illustrated in the accompanying drawings. Where the following description refers to the drawings, unless otherwise indicated, like numerals in different drawings indicate the same or similar elements. The embodiments described in the following exemplary embodiments do not represent all embodiments consistent with the present application. Rather, they are merely examples of apparatuses and methods consistent with some aspects of the present application as detailed in the appended claims.

The terminology used in this application is for the purpose of describing particular embodiments only and is not intended to limit this application. As used in this application and the appended claims, the singular forms “a”, “the”, and “the” are also intended to include plural forms unless the context clearly indicates other meanings. It should also be understood that the term “and/or” as used herein refers to and encompasses any or all possible combinations of one or more associated listed items.

It should be understood that although the terms first, second, third, etc., may be used in this application to describe various information, these information should not be limited to these terms. These terms are only used to distinguish the same type of information from each other. For example, without departing from the scope of this application, the first information may also be referred to as second information, and similarly, the second information may also be referred to as first information. Depending on context, the word “if” as used herein may be interpreted as “when” or “when” or “in response to a determination.”

One or more embodiments of the present application provide an array substrate, a light emitting substrate and a display device. The array substrate, the light emitting substrate and the display device in the embodiments of the present application will be described in detail below with reference to the accompanying drawings. In case of no conflict, the features in the embodiments described below may complement or be combined with each other.

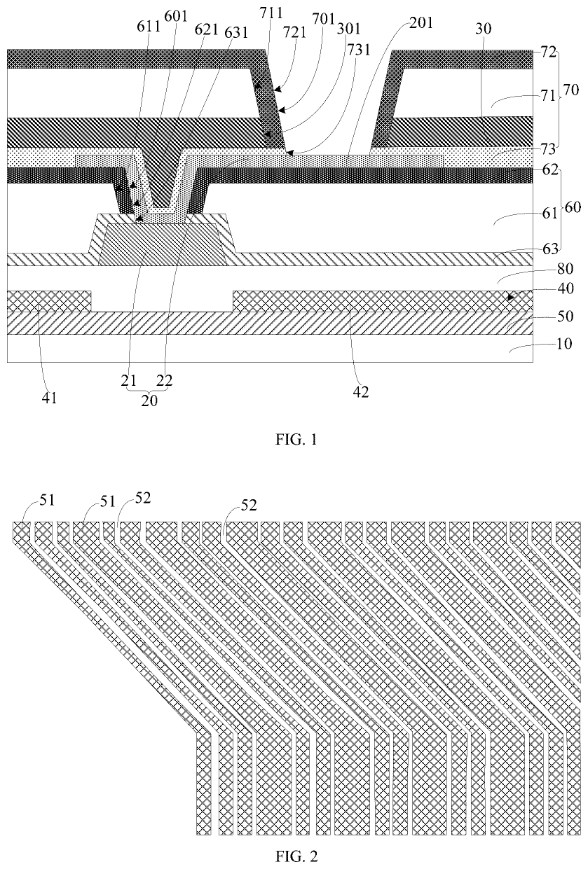

One or more embodiments of the present application provide an array substrate. As shown in FIG. 1, the array substrate includes a base substrate 10, a conductive layer 20, a light adjustment layer 30, a plurality of signal lines and a protective layer 40.

The conductive layer 20 is located on a side of the base substrate 10 and includes a plurality of pads 201, and the pads 201 are configured to be electrically connected with one or more electronic elements. The light adjustment layer 30 is located on a side of the conductive layer 20 away from the base substrate 10. The plurality of signal lines are located on a side of the base substrate 10 away from the conductive layer 20 and electrically connected with the pads 201. An orthographic projection of at least part of the light adjustment layer 30 on the base substrate 10 does not overlap an orthographic projection of the conductive layer 20 on the base substrate 10, and is located in a gap between orthographic projections of adjacent signal lines on the base substrate 10. The protective layer 40 is located between the light adjustment layer 30 and the base substrate 10, and the orthographic projection of the protective layer 40 on the base substrate 10 at least covers the orthographic projection of the at least part on the base substrate 10. The protective layer 40 is configured to attenuate energy of laser light used for preparing the signal lines when the laser light propagates to the protective layer 40.

The plurality of signal lines are provided on a side of the base substrate 10 away from the conductive layer 20. As shown in FIG. 2, there is a gap 52 between adjacent signal lines 51. When preparing the signal lines 51 on the side of the base substrate 10 away from the conductive layer 20, a large-area conductive material layer is first formed on the side of the base substrate 10 away from the conductive layer 20, and then laser etching is performed on the conductive material layer. The region that is kept is the signal lines 51 and the region that is removed by laser etching is the gaps 52. That is, the path of laser etching is the gaps 52 between adjacent signal lines 51. During the process of etching the conductive material layer by the laser, laser will pass through the base substrate 10 and propagate to the light adjustment layer 30.

According to the array substrate provided by the embodiments of the present application, the light adjustment layer is arranged on the side, away from the base substrate, of the conductive layer and can reduce an influence of reflection effect of the conductive layer on the light-emitting effect of the light emitting substrate where the array substrate is located, and the problem of color shift of the light emitting substrate can be alleviated. The protective layer is arranged between the light adjustment layer and the base substrate. The orthographic projection of at least part of the light adjustment layer on the base substrate is not overlapped with the orthographic projection of the conductive layer on the substrate but between gaps of the orthographic projections of adjacent signal lines on the base substrate and the orthographic projection of the protective layer on the base substrate covers the orthographic projection of the at least part of the light adjustment layer on the base substrate. The energy of the laser is weakened when the laser adopted for preparing the signal lines propagates to the protective layer, and thus the energy of the laser is weak when the laser is transmitted to the at least part of the light adjustment layer, so that the problems that the at least part of the light adjustment layer is subjected to bulging, discoloration, peeling from the adjacent film layer and the like due to absorption of a large amount of laser energy can be avoided. For the part where the orthographic projection of the conductive layer on the base substrate is not overlapped with the orthographic projection of the protective layer on the base substrate, when the laser is transmitted to the area, the energy of the laser can also be weakened, avoiding the problem of bulging, discoloration, peeling from the adjacent film layer and the like due to absorption of a large amount of energy. It can be known that with the embodiments of the present application, the reliability of the array substrate can be improved, and the product yield can be improved.

In an embodiment, the base substrate 10 may be a flexible substrate or a rigid substrate. A material of the flexible substrate may include one or more of polyimide, polyethylene terephthalate, polycarbonate, and organic resin material. The organic resin material may include epoxy resin, triazine, silicone resin, polyimide, or the like. The rigid substrate includes any one of a glass substrate, a quartz substrate, a sapphire substrate, a ceramic substrate, and the like; or any one of a semiconductor substrate such as a monocrystalline semiconductor substrate or a polycrystalline semiconductor substrate made of silicon or silicon carbide, a compound semiconductor substrate such as silicon germanium, an SOI (Silicon On Insulator) substrate, and the like.

In an embodiment, as shown in FIG. 1, the protective layer 40 is located on a side of the conductive layer 20 away from the light adjustment layer 30. In this way, shape and position of the protective layer 40 may be set according to a part of the light adjustment layer 30 to be protected, without a need to consider the position of the conductive layer 20, which is more conducive to avoiding the problems of bulging, discoloration, peeling from an adjacent film layer and the like of the light adjustment layer 30.

In an embodiment, as shown in FIG. 1, the array substrate further includes a buffer layer 50 located between the conductive layer 20 and the base substrate 10. A material of the buffer layer 50 may be an inorganic material, for example, including at least one of silicon oxide or silicon nitride.

In one embodiment, the electronic elements electrically connected with the pads 201 include light emitting elements with a dimension on the magnitude of several hundred microns and below, and the electronic elements may also include driving chips with a dimension on the magnitude of several hundred microns and below. The light emitting elements with a dimension on the magnitude of several hundred microns and below may be a mini LED or a micro LED. A size of the mini LED ranges from about 100 μm to about 500 μm, and a size of the micro LED is less than 100 μm. The driving chips may be chips for providing a signal to the light emitting elements to cause the light emitting elements to emit light.

In an embodiment, a first conductive sub-layer 21 is generally configured to arrange various signal lines, such as a common voltage line, a driving voltage line, a source power supply line, a source address line, a data line, and the like. Optionally, a thickness of the first conductive sub-layer 21 ranges from 1.5 μm to 7 μm, and a material thereof includes copper. For example, a laminated material such as MoNb/Cu/MoNb may be formed by sputtering. A bottom layer MoNb is used to improve adhesion, a middle layer Cu is used to transmit an electrical signal, and a top layer MoNb is used to prevent oxidation. The first conductive sub-layer may alternatively be formed by electroplating. A seed layer MoNiTi is formed first to increase grain nucleation density, and then the anti-oxidation layer MoNiTi is formed after electroplating.

In an embodiment, as shown in FIG. 1, the conductive layer 20 includes a first conductive sub-layer 21 and a second conductive sub-layer 22 located on a side of the first conductive sub-layer 21 away from the base substrate.

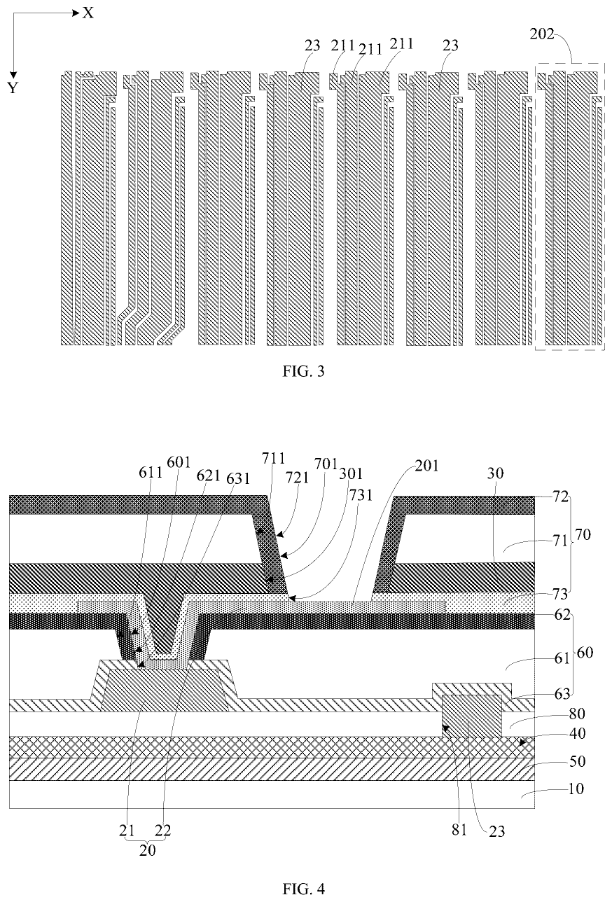

In an embodiment, as shown in FIG. 3, the signal lines 211 located in the first conductive sub-layer 21 are arranged in parallel along the first direction X, and the signal lines 211 extend along the second direction Y. The signal lines 211 located in the first conductive sub-layer 21 may be divided into a plurality of signal line groups 202. Each of the signal line groups 202 includes five different signal lines 211 disposed adjacent to each other, and the signal lines 211 of each signal line group 202 may be configured to provide signals to a same column of light-emitting elements.

In one embodiment, the signal lines in the first conductive sub-layer 21 are connected with respective signal lines located on the side of the base substrate 10 away from the conductive layer 20 through wires disposed on a side edge of the array substrate. This arrangement helps to reduce a border size of the array substrate and improve user experience.

In an embodiment, the second conductive sub-layer 22 includes a plurality of pads 201 and a plurality of connection lines, and the connection lines are, for example, wires connecting a plurality of light-emitting devices of a same light-emitting unit in series. Optionally, a thickness of the second conductive sub-layer is about 6000 Å, and a material of the second conductive sub-layer may be a laminated material such as MoNb/Cu/CuNi. A bottom layer of MoNb is used to improve adhesion, a middle layer of Cu is used to transmit an electrical signal, and a top layer of CuNi may both prevent oxidation and improve die bonding firmness.

In an embodiment, as shown in FIG. 1, the array substrate further includes a first insulating material layer 60 located between the first conductive sub-layer 21 and the second conductive sub-layer 22. The first insulating material layer 60 is provided with a first opening 601, and the first conductive sub-layer 21 is lapped/contacted with the second conductive sub-layer 22 through the first opening 601. The first insulating material layer 60 insulates portions of the first conductive sub-layer 21 and the second conductive sub-layer 22 that do not need to be electrically connected, and can ensure that a capacitance between the connection wire and the signal line meets requirements. Other insulating layers may be disposed between the first conductive sub-layer 21 and the second conductive sub-layer 22.

In one embodiment, as shown in FIG. 1, the first insulating material layer 60 includes a first organic layer 61. The first opening 601 includes a first sub-opening 611 disposed in the first organic layer 61.

In an embodiment, as shown in FIG. 1, the first insulating material layer 60 further includes a first inorganic layer 62 located on a side of the first organic layer 61 away from the base substrate 10. The first opening 601 includes a second sub-opening 621 disposed in the first inorganic layer 62, and an edge of an orthographic projection of the second sub-opening 621 on the base substrate 10 is located inside an edge of an orthographic projection of the first sub-opening 611 on the base substrate. In this way, the first inorganic layer 62 covers a side surface of the first sub-opening 611 of the first organic layer 61, which helps to block water vapor and reduce an amount of water vapor intruding into the first conductive sub-layer, and thus helps to improve the reliability of the array substrate.

In an embodiment, as shown in FIG. 1, the first insulating material layer 60 further includes a second inorganic layer 63 located on a side of the first organic layer 61 close to the base substrate 10, and the first opening 601 further includes a third sub-opening 631 disposed in the second inorganic layer 63. An orthographic projection of the third sub-opening 631 on the base substrate 10 joins the orthographic projection of the second sub-opening 621 on the base substrate 10. In this way, the first inorganic layer 62 and the second inorganic layer 63 may be manufactured by using a same mask, which helps reduce a manufacturing cost of the array substrate.

In an embodiment, as shown in FIG. 1, the array substrate further includes a second insulating material layer 70 located on a side of the second conductive sub-layer 22 away from the base substrate 10. The second insulating material layer 70 is provided with a second opening 701, and the second opening 701 exposes the pad 201. The second insulating material layer 70 may protect the conductive layer 20.

In one embodiment, as shown in FIG. 1, the second insulating material layer 70 includes a second organic layer 71. The second opening 701 includes a fourth sub-opening 711 disposed in the second organic layer 71.

In an embodiment, as shown in FIG. 1, the second insulating material layer 70 further includes a third inorganic layer 72 located on a side of the second organic layer 71 away from the base substrate 10. The second opening 701 includes a fifth sub-opening 721 disposed in the third inorganic layer 72, and an edge of an orthographic projection of the fifth sub-opening 721 on the base substrate 10 is located inside an edge of an orthographic projection of the fourth sub-opening 711 on the base substrate. In this way, the third inorganic layer 72 covers a side surface of the fourth sub-opening 711 of the second organic layer 71, which helps to block water vapor and reduce an amount of water vapor intruding into the second conductive sub-layer, and helps to improve the reliability of the array substrate.

In an embodiment, as shown in FIG. 1, the second insulating material layer 70 further includes a fourth inorganic layer 73 located on a side of the second organic layer 71 close to the base substrate 10, and the second opening 701 further includes a sixth sub-opening 731 disposed in the fourth inorganic layer 73. An orthographic projection of the sixth sub-opening 731 on the base substrate 10 joins the orthographic projection of the fifth sub-opening 721 on the base substrate 10. In this way, the third inorganic layer 72 and the fourth inorganic layer 73 may be manufactured by using a same mask, which helps reduce the manufacturing cost of the array substrate.

In an embodiment, as shown in FIG. 1, the light adjustment layer 30 is located between the fourth inorganic layer 73 and the second organic layer 71. The light adjustment layer 30 is provided with a third opening 301, and the third opening 301 exposes the pad 201. The light adjustment layer 30 may be provided with a plurality of third openings 301, and the third openings 301 may be in one-to-one correspondence with the pads 201. The edge of the orthographic projection of the fifth sub-opening 721 on the base substrate 10 is located inside an edge of an orthographic projection of the third opening 301 on the base substrate. In this way, the third inorganic layer 72 covers a side surface of the third opening 301 of the light adjustment layer 30, which helps to block water vapor and reduce an amount of water vapor intruding into the second conductive sub-layer, and helps to improve the reliability of the array substrate.

In one embodiment, the light adjustment layer 30 may be black.

In one embodiment, the protective layer 40 is made of a conductive material. As shown in FIG. 1, the array substrate further includes an insulating layer 80 located between the conductive layer 20 and the protective layer 40. The insulating layer 80 insulates the conductive layer 20 from the protective layer 40. A material of the insulating layer 80 may be an inorganic material, for example, including at least one of silicon nitride and silicon oxide.

In an embodiment, as shown in FIG. 1, the protective layer 40 is not connected with an electrical signal, and the protective layer 40 includes a plurality of protective structures 42 spaced apart from each other. In this way, an area of each protective structure 42 is relatively small, and when an accompanying capacitor is formed in an overlapping region between the protective structure and the conductive layer 20, an accompanying capacitance can be relatively small, and influence on the electrical performance of the array substrate is reduced. Besides, the area of the protective layer 40 can be relatively small, so that in the process of dry etching the insulating film layer on the side, away from the base substrate, of the protective layer of the array substrate, burn-out of an electrode of dry etching equipment by an electric arc generated in the dry etching process due to large area of the protective layer 40 can be avoided.

In another embodiment, the protective layer 40 is made of a conductive material, and the protective layer 40 is connected with a constant electrical signal. With such an arrangement, an overlapping region between the protection structure and the conductive layer 20 can be prevented from forming an accompanying/associated capacitor, and the protective layer 40 can be prevented from affecting the electrical performance of the array substrate.

Further, as shown in FIG. 4, the conductive layer 20 includes a conductive wire 23 connected with a constant signal, the insulating layer 80 is provided with a through hole 81, and the conductive wire 23 is lapped with/contacts the protective layer 40 through the through hole 81. In this way, the protective layer 40 is electrically connected with the conductive wire 23 of the conductive layer 20 to be connected with a constant electrical signal, and compared with a solution in which an additional signal line connecting the constant electrical signal is arranged to be connected with the protective layer 40, it is conducive to simplify a manufacturing process and structural complexity of the array substrate.

Further, the conductive wire 23 may be a common voltage line. The conductive wire 23 is located in the first conductive sub-layer 21.

In an embodiment, an orthographic projection of the protective layer 40 on the base substrate 10 covers a gap between orthographic projections of any two adjacent signal lines located on the side of the base substrate 10 away from the conductive layer 20 on the base substrate 10. In this way, laser used to etch the conductive material between any two adjacent signal lines passes through the protective layer 40 and is weakened by the protective layer 40 during propagation to the light adjustment layer 30.

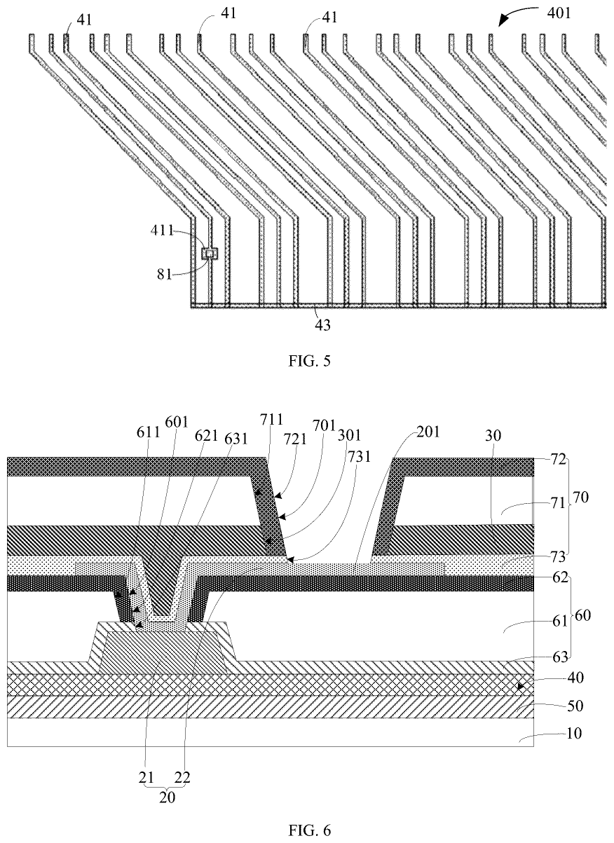

In an embodiment, as shown in FIG. 5, the protective layer 40 includes a plurality of protective portions 41, and an orthographic projection of one protective portion 41 on the base substrate 10 covers an orthographic projection of one gap on the base substrate 10. In this way, the area of the protective layer 40 can be reduced on the premise that the protective layer effectively avoids the problems of bulging, discoloration, peeling off from the adjacent film layer(s) and the like of the light adjustment layer 30, so as to avoid burn-out of an electrode of dry etching equipment by electric arc generated due to relatively large area of the protective layer in the process of dry etching the insulating film layer of the array substrate on the side of the protective layer away from the base substrate. In some embodiments, the protective portions 41 may correspond to gaps between adjacent signal lines one by one, and an orthographic projection of each protective portion 41 on the base substrate 10 covers an orthographic projection of a corresponding gap on the base substrate 10.

Further, an edge of an orthographic projection of the protective portion 41 on the base substrate 10 is located outside an edge of an orthographic projection of one gap on the base substrate 10. In this way, when the laser passes through the corresponding protective portion 41, the energy weakening effect of the protective portion 41 on the laser is better, which is more conducive to improving the reliability and yield of the array substrate.

Further, a distance between the edge of the orthographic projection of the protective portion 41 on the base substrate 10 and the edge of the orthographic projection of the corresponding gap on the base substrate 10 is about 10 μm. With such an arrangement, the area of the protective layer 40 can be prevented from being excessively large on the premise of ensuring the weakening effect of the protective layer on the energy of the laser.

In an embodiment, the protective layer 40 includes at least one protective portion group. FIG. 5 shows a partial structure of a protective portion group. As shown in FIG. 5, the protective portion group includes a plurality of protective portions 41 arranged in parallel. The array substrate includes at least one signal line group, and FIG. 2 is a partial structural schematic diagram of one signal line group. One signal line group includes a plurality of signal lines 51 arranged in parallel, and an arrangement direction/trend of the signal lines 51 of the signal line group is the same as an arrangement direction/trend of the protective portions 41 of the protective portion group 401. The protective layer 40 further includes a connecting portion 43, and at least two protective portions 41 in a same protective portion group 401 are connected through the connecting portion. By providing at least two protective portions 41 in the same protective portion group 401 to be electrically connected through the connecting portion 43, in the protective portions 41 connected with the same connecting portion, connection of one of the protective portions 41 with a constant electrical signal is enough to have protective portions 41 connected with the same connecting portion all be connected with the constant electrical signal, which helps simplify the structure of the array substrate.

Further, ends, on a same side, of the protective portions 41 of the same protective portion group 401 are respectively connected with the connecting portion 43. That is, the protective portions 41 of the same protective portion group 401 are all electrically connected through the connecting portion 43, and connection of one of the protective portions 41 with a constant electrical signal is enough to have the protective portions 41 of the protective portion group 401 all be connected with the constant electrical signal, thereby further simplifying the structure of the array substrate.

In an embodiment, as shown in FIG. 5, in a same protective portion group 401, at least one protective portion 41 includes a lapping part 411, an orthographic projection of the through hole 81 of the insulating layer 80 on the base substrate 10 falls within an orthographic projection of the lapping part 411 on the base substrate 10, and the conductive wire 23 connected with the constant signal is lapped with the lapping part 411 through the through hole 81 of the insulating layer 80. In the embodiment shown in FIG. 5, only one protective portion 41 in the same protective portion group 401 includes a lapping part 411. In other embodiments, a plurality of protective portions 41 in the same protective portion group 401 may include a lapping part, and each lapping part is lapped with the conductive wire 23 via through holes in the insulating layer.

In an embodiment, when the material of the protective layer 40 is a conductive material, the material of the protective layer 40 may include a metal material with a relatively high reflectivity. For example, the material of the protective layer 40 includes copper. In some embodiments, the material of the protective layer 40 may be copper. In this way, when the laser propagates to the protective layer, the protective layer 40 reflects at least part of the laser to reduce the energy of the laser propagating to the light adjustment layer 30. Meanwhile, the protective layer has relatively stable properties, and when the laser propagates to the protective layer 40, the protective layer 40 does not suffer from problem such as bulging and peeling from adjacent film layer(s).

In an embodiment, the protective layer 40 is made of a non-conductive material, and an orthographic projection of the protective layer 40 on the base substrate 10 covers an orthographic projection of the light adjustment layer 30 on the base substrate 10. When the protective layer 40 is made of a non-conductive material, it is unnecessary to provide an insulating layer between the protective layer 40 and the conductive layer 20, which facilitates simplification of the manufacturing process and the structural complexity of the array substrate.

Further, as shown in FIG. 6, an orthographic projection of the protective layer 40 on the base substrate 10 may cover the base substrate 10. That is, the protective layer is an entire planer layer, and no patterning process is involved when the protective layer 40 is formed, which facilitates simplification of the preparation process of the array substrate.

Further, a thickness of the protective layer 40 is greater than or equal to 1000 angstroms. In this way, the protective layer 40 effectively reduces the energy of the laser.

In some embodiments, the protective layer 40 is made of amorphous silicon. In this way, it can not only ensure that the protective layer 40 effectively attenuates the energy of the laser, but also ensure that the protective layer 40 has relatively stable properties. When the laser is transmitted to the protective layer 40, the protective layer 40 does not suffer from problems such as bulging and peeling from adjacent film layer(s) due to the action of the laser, thereby improving the reliability of the array substrate.

Embodiments of the present application further provide a light emitting substrate including one or more electronic elements and the array substrate according to any one of the above embodiments. The electronic elements are connected with the pads; and the electronic elements include light emitting elements.

In one embodiment, the light-emitting element is a mini LED or a Micro LED.

In an embodiment, the light-emitting element further includes a driving chip, and the driving chip may be a chip configured to provide a signal to the light-emitting element to cause the light-emitting element to emit light.

Embodiments of the present application further provide a display device including the above-mentioned light emitting substrate.

In some embodiments, the display device may be a liquid crystal display device including a liquid crystal panel and a backlight disposed on a non-display side of the liquid crystal panel. The backlight includes the light emitting substrate described in any one of the foregoing embodiments.

In another embodiment, the light emitting substrate in the display device is used as a display substrate. When the light emitting substrate is used as a display substrate, each light-emitting element serves as one sub-pixel.

The application of the display device is not specifically limited, and the display device may be any product or component having a flexible display function, such as a television, a notebook computer, a tablet computer, a wearable display device, a mobile phone, a vehicle-mounted display, navigator, an electronic book, a digital photo frame, an advertisement light box, or the like.

It should be noted that in the drawings, the dimensions of layers and regions may be exaggerated for clarity of illustration. Also, it is understood that when an element or layer is referred to as being “on” another element or layer, it may be directly on the other element, or intervening layers may be present. Additionally, it is understood that when an element or layer is referred to as being “under” another element or layer, it may be directly under the other element, or more than one intervening layer or element may be present. Additionally, it will be appreciated that when a layer or element is referred to as being “between” two layers or elements, it may be the only layer between two layers or elements, or more than one intermediate layer or element may also be present. Like reference numerals indicate like elements throughout.

Other embodiments of the present application will be readily apparent to those skilled in the art upon consideration of the specification and practice of the disclosure herein. This application is intended to cover any variations, uses, or adaptations of this application that follow the general principles of this application and include common knowledge or conventional technical means in the art that are not disclosed in this application. The specification and embodiments are to be regarded as exemplary only, and the true scope and spirit of the present application are indicated by the following claims.

It should be understood that the present application is not limited to the precise structure described above and shown in the accompanying drawings, and various modifications and changes may be made without departing from the scope thereof. The scope of the present application is limited only by the appended claims.

1. An array substrate, comprising:
a base substrate;
a conductive layer located on a side of the base substrate, where the conductive layer comprises a plurality of pads configured to be electrically connected with electronic elements;
a light adjustment layer located on a side of the conductive layer away from the base substrate;
a plurality of signal lines located on a side of the base substrate away from the conductive layer; wherein an orthographic projection of at least part of the light adjustment layer on the base substrate does not overlap an orthographic projection of the conductive layer on the base substrate and is located in gaps between orthographic projections of adjacent signal lines on the base substrate;
a protective layer located between the light adjustment layer and the base substrate, wherein an orthographic projection of the protective layer on the base substrate at least partially covers the orthographic projection of the at least part of the light adjustment layer on the base substrate.

2. The array substrate according to claim 1, wherein the protective layer is made of a conductive material, and the protective layer is connected with a constant electrical signal.

3. The array substrate according to claim 2, wherein the orthographic projection of the protective layer on the base substrate covers gaps between orthographic projections of any two adjacent signal lines among the signal lines on the base substrate.

4. The array substrate according to claim 3, wherein the protective layer comprises a plurality of protective portions, and an orthographic projection of a protective portion of the protective portions on the base substrate covers an orthographic projection of a gap of the gaps on the base substrate.

5. The array substrate according to claim 4, wherein an edge of an orthographic projection of the protective portion on the base substrate is located outside an edge of the orthographic projection of the gap on the base substrate.

6. The array substrate according to claim 4, wherein the protective layer comprises at least one protective portion group, and the at least one protective portion group each comprises multiple protective portions among the protective portions and arranged in parallel;
the array substrate comprises at least one signal line group, and the at least one signal line group each comprises multiple signal lines among the plurality of signal lines and arranged in parallel, and an arrangement trend of the multiple signal lines of the signal line group is same as an arrangement trend of the multiple protective portions of the protective portion group;
the protective layer further comprises a connecting portion, and at least two of the multiple protective portions in a same protective portion group are connected through the connecting portion.

7. The array substrate according to claim 6, wherein ends, that are on a same side, of the multiple protective portions in the same protective portion group are respectively connected with the connecting portion.

8. The array substrate according to claim 1, wherein the protective layer is located on a side of the conductive layer away from the light adjustment layer.

9. The array substrate according to claim 8, wherein the protective layer is made of a conductive material, and the array substrate further comprises an insulating layer located between the protective layer and the conductive layer.

10. The array substrate according to claim 9, wherein the conductive layer comprises a conductive wire connected with a constant signal, the insulating layer is provided with a through hole, and the conductive wire is lapped with the protective layer through the through hole.

11. The array substrate according to claim 1, wherein the protective layer is made of a non-conductive material, and the orthographic projection of the protective layer on the base substrate covers an orthographic projection of the light adjustment layer on the base substrate.

12. The array substrate according to claim 1, wherein the conductive layer comprises a first conductive sub-layer and a second conductive sub-layer located on a side of the first conductive sub-layer away from the base substrate, and the pads are located in the second conductive sub-layer.

13. A light emitting substrate, comprising one or more electronic elements and an array substrate, wherein the electronic elements are connected with the pads, and the electronic elements comprise light emitting elements;
wherein the array substrate comprises:
a base substrate;
a conductive layer located on a side of the base substrate, where the conductive layer comprises a plurality of pads configured to be electrically connected with the electronic elements;
a light adjustment layer located on a side of the conductive layer away from the base substrate;
a plurality of signal lines located on a side of the base substrate away from the conductive layer; wherein an orthographic projection of at least part of the light adjustment layer on the base substrate does not overlap an orthographic projection of the conductive layer on the base substrate and is located in gaps between orthographic projections of adjacent signal lines on the base substrate;
a protective layer located between the light adjustment layer and the base substrate, wherein an orthographic projection of the protective layer on the base substrate at least partially covers the orthographic projection of the at least part of the light adjustment layer on the base substrate.

14. The light emitting substrate according to claim 13, wherein the light-emitting elements are mini LEDs or Micro LEDs.

15. The light emitting substrate according to claim 13, wherein the protective layer is made of a conductive material, and the protective layer is connected with a constant electrical signal.

16. The light emitting substrate according to claim 15, wherein the orthographic projection of the protective layer on the base substrate covers gaps between orthographic projections of any two adjacent signal lines among the signal lines on the base substrate.

17. The light emitting substrate according to claim 13, wherein the protective layer is located on a side of the conductive layer away from the light adjustment layer.

18. The light emitting substrate according to claim 17, wherein the protective layer is made of a conductive material, and the array substrate further comprises an insulating layer located between the protective layer and the conductive layer.

19. The light emitting substrate according to claim 13, wherein the protective layer is made of a non-conductive material, and the orthographic projection of the protective layer on the base substrate covers an orthographic projection of the light adjustment layer on the base substrate.

20. A display device, comprising the light emitting substrate according to claim 13.
